(19) United States
(12) Patent Application Publication
(10) Pub. No.: US 2024/0063142 A1
(43) Pub. Date: Feb. 22, 2024

(54) DIE CRACK MITIGATION IN MULTI-CHIP COMPOSITE IC STRUCTURES

(71) Applicant: Intel Corporation, Santa Clara, CA (US)

(72) Inventors: Adel Elsherbini, Chandler, AZ (US); Wenhao Li, Chandler, AZ (US); Bhaskar Jyoti Krishnatreya, Hillsboro, OR (US); Tushar Talukdar, Wilsonville, OR (US); Botao Zhang, Gilbert, AZ (US); Yi Shi, Chandler, AZ (US); Haris Khan Niazi, Scottsdale, AZ (US); Feras Eid, Chandler, AZ (US); Nagatoshi Tsunoda, Tsukuba-shi (JP); Xavier Brun, Hillsboro, OR (US); Mohammad Enamul Kabir, Portland, OR (US); Omkar Karhade, Chandler, AZ (US); Shawna Liff, Scottsdale, AZ (US); Jiraporn Seangatith, Chandler, AZ (US)

(73) Assignee: Intel Corporation, Santa Clara, CA (US)

(21) Appl. No.: 17/891,666

(22) Filed: Aug. 19, 2022

(51) Int. Cl. H01L 23/00; H01L 23/367; H01L 23/31; H01L 23/498; H01L 21/48; H01L 21/56; H01L 25/065; H01L 25/00

(52) U.S. Cl. CPC H01L 23/562; H01L 23/367; H01L 23/3128; H01L 23/49827; H01L 23/49838; H01L 21/486; H01L 21/565; H01L 25/0655; H01L 25/50

(57) ABSTRACT

Multi-die packages including IC die crack mitigation features. Prior to the bonding of IC dies to a host substrate, the IC dies may be shaped, for example with a corner radius or chamfer. After bonding the shaped IC dies, a fill comprising at least one inorganic material may be deposited over the IC dies, for example to backfill a space between adjacent IC dies. With the benefit of a greater IC die sidewall slope and/or smoother surface topology associated with the shaping process, occurrences of stress cracking within the fill and concomitant damage to the IC dies may be reduced. Prior to depositing a fill, a barrier layer may be deposited over the IC die to prevent cracks that might form in the fill material from propagating into the IC die.

### BACKGROUND

Monolithic integrated circuit (IC) fabrication has restrictions that may limit a final product's performance, and thus different versions of IC die (dis)integration are being investigated. To date however, these techniques and architectures generally suffer from certain drawbacks such as high cost, lower insertion efficiency, and increased z-height.

IC die disintegration techniques rely on advances in multi-die integration at the package level or at a level between monolithic IC die fabrication and the package level. In electronics manufacturing, IC packaging is a stage of semiconductor device fabrication in which an IC that has been fabricated on a chip (or die) comprising a semiconducting material is assembled into a “package” that can protect the IC chip from physical damage and support electrical contacts that connect the IC to a scaled host component, such as an organic package substrate, or a printed circuit board. Multiple chips can be similarly assembled together, for example, into a multi-chip package (MCP).

Multi-chip architectures may advantageously combine IC chips from heterogeneous silicon processes and/or combine small dis-aggregated chips from identical silicon processes. However, there are many challenges with integrating multiple IC die into such a chip-scale unit. For example, inter-die fill material can suffer high stress, for example during thermal cycling as a multi-chip composite structure is fabricated. This high stress can induce cracks that readily propagate into a device layer of one or more IC dies, reducing functional device yield.

Accordingly, architectures that reduce die cracking in multi-die composite IC structures, and fabrication techniques associated with those architectures, may be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for mitigating die cracks in a multi-die composite IC device structure, in accordance with some embodiments;

FIG. 2 is a cross-sectional view of a monolithic IC die substrate during singulation, in accordance with some embodiments;

FIG. 3A is a cross-sectional view of singulated IC dies with substantially vertical edge sidewalls, in accordance with some embodiments;

FIG. 3B is a cross-sectional view of singulated IC dies with chamfered edge sidewalls, in accordance with some embodiments;

FIG. 3C is a cross-sectional view of singulated IC dies with radiused edged sidewalls, in accordance with some alternative embodiments;

FIG. 4A is a cross-sectional view of IC dies from FIG. 3A bonded to a multi-chip composite structure, in accordance with some embodiments;

FIG. 4B is a cross-sectional view of IC dies from FIG. 3B bonded to a multi-chip composite structure, in accordance with some alternative embodiments;

FIG. 4C is a cross-sectional view of IC dies from FIG. 3C bonded to a multi-chip composite structure, in accordance with some alternative embodiments;

FIG. 5A is a cross-sectional view of a crack barrier over the multi-chip composite structure illustrated in FIG. 4A, in accordance with some embodiments;

FIG. 5B is a cross-sectional view of a crack barrier over the multi-chip composite structure illustrated in FIG. 4B, in accordance with some embodiments;

FIG. 5C is a cross-sectional view of a crack barrier over the multi-chip composite structure illustrated in FIG. 4C, in accordance with some embodiments;

FIG. 6A is a cross-sectional view of a crack barrier over the multi-chip composite structure illustrated in FIG. 5A, in accordance with some embodiments;

FIG. 6B is a cross-sectional view of a crack barrier over the multi-chip composite structure illustrated in FIG. 5B following an etchback of the barrier, in accordance with some embodiments;

FIG. 6C is a cross-sectional view of a crack barrier over the multi-chip composite structure illustrated in FIG. 5C following an etchback of the barrier, in accordance with some embodiments;

FIG. 7A is a cross-sectional view of the multi-chip composite structure illustrated in FIG. 6A following die gap fill with one or more inorganic materials, in accordance with some embodiments;

FIG. 7B is a cross-sectional view of the multi-chip composite structure illustrated in FIG. 6B following die gap fill with one or more inorganic materials, in accordance with some embodiments;

FIG. 7C is a cross-sectional view of the multi-chip composite structure illustrated in FIG. 6C following die gap fill with one or more inorganic materials, in accordance with some embodiments;

FIG. 8 is a cross-sectional view of a multi-chip composite structure following planarization of the die gap fill with adjacent IC dies, in accordance with some embodiments;

FIG. 9 is a cross-sectional view of a multi-chip composite structure ready for packaging, in accordance with some embodiments;

FIG. 10 illustrates a system including the multi-chip composite structure illustrated in FIG. 9 attached to a host component with FLI features, in accordance with some embodiments;

FIG. 11 illustrates a mobile computing platform and a data server machine employing a multi-chip composite IC structure having crack mitigation, in accordance with some embodiments; and

FIG. 12 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Quasi-monolithically integrated die structures including multiple IC die directly bonded to a host substrate and covered with an inorganic gap fill material are described herein. These structures may be referred to as a “composite” or “quasi-monolithic” because at least some of the IC dies are directly bonded to the host substrate rather than being interconnected with a joining material, such as solder. Also, the inorganic fill material described herein is similar to the materials found in monolithic ICs, in contrast to the organic materials (e.g., epoxy) found in IC die packages.

For bonded IC dies where metal features of the host substrate are fused to those of the IC die, the resulting composite, quasi-monolithic structure may comprise a hybrid bonded interface of both metallurgically interdiffused metals and chemically bonded insulators. Prior to IC die bonding, each (active) IC die may be fabricated in a monolithic process separate from each other. As such, each IC die may be fabricated with the same or different wafer fab technologies. Each IC die may be fabricated to support face-to-face, face-to-back, or back-to-back bonding with another IC die. In accordance with some embodiments herein, IC die singulation and/or post-singulation processing of the IC die comprises shaping backside edges and/or corners of the IC die to make or gradual a transition between IC die edge sidewall and backside surface.

After bonding the shaped IC dies, the more gradual transitions in the IC die topology may reduce the prevalence of high stress centers within an inorganic fill material deposited over the IC dies. With fewer high-stress points cracks may be less likely to develop, for example during thermal cycling of a composite IC die structure as it is fabricated. Accordingly, damage to the IC die associated with the propagation of cracks into the IC die may be mitigated.

As further described below, a crack barrier layer may be deposited over bonded IC die prior to deposition of an inorganic gap-fill material. The crack barrier layer may further smoothen the IC die surface and/or prevent the propagation of cracks into the IC die, for example because of the barrier materials high modulus of toughness. Voids may also be formed between the IC die and inorganic fill material at locations of high stress so that cracks will terminate at the void rather than entering the IC die. Delamination of the gap-fill material may be avoided by limiting the size and location of the voids through a self-aligned technique.

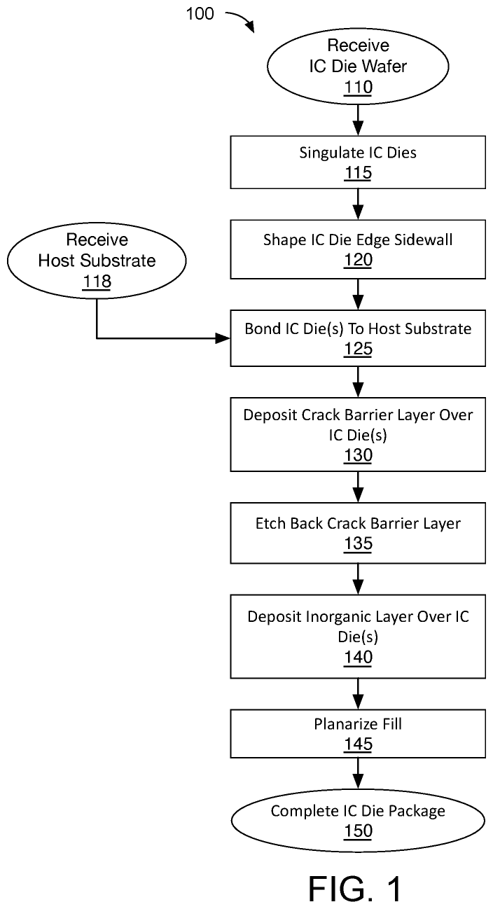

A number of different fabrication methods may be practiced to form a composite IC die structure having one or more of the crack mitigation features or attributes described herein. FIG. 1 illustrates a flow diagram of methods 100 for forming a composite IC die structure that includes some exemplary die crack mitigation features. Notably, not all blocks of methods 100 need be practiced in combination. Instead, one or more blocks of methods 100 need not be practiced (i.e., skipped). The blocks of methods 100 may also be arranged into a different order where the operation performed at each block does not inherently demand a particular order.

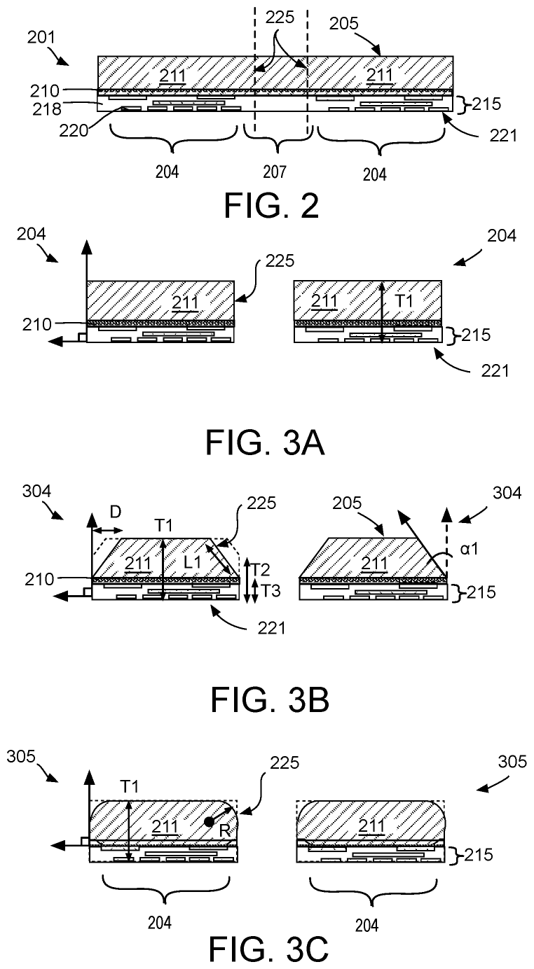

Methods 100 begin at input 110 where an IC die wafer comprising a plurality of contiguous IC dies is received. The IC die wafer may be any output typical of an IC die wafer fab, for example having a diameter of 300-450 mm. At block 115, individual IC dies are singulated from the wafer. Singulation at block 115 may include one or more processes such as, but not limited to, sawing, scribing, laser ablation, plasma etching, or wet etching. In the example further illustrated in FIG. 2, a wafer 201 includes multiple IC dies 204. Wafer 201 has a back side 205 comprising a substrate material 211. In some examples, substrate material 211 is silicon. In other examples, substrate material 211 is an alternative crystalline material, such as, but not limited to, germanium, SiₓGe₁₋ₓ, GeₓSm₁₋ₓ or silicon carbide. In still other examples, substrate material 211 is a glass (e.g., silica), which can have flatness approximately equal to that of crystalline substrates, but at a lower cost.

Each IC die 204 is an “active” IC die that includes a device layer 210 fabricated in, or on, substrate material 211. Device layer 210 may be homogenous with substrate material 211, or not (e.g., a transferred substrate). Device layer 210 (and a homogeneous IC die substrate material 211) may include any semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, IC device layer 210 is a Group III-V material comprising a Group III majority constituent and a Group IV majority constituent (e.g., InGaAs, GaAs, GaSb, InGaSb). IC die device layer 210 may have a thickness of 50-1000 nm, for example. IC die device layer 210 need not be a continuous layer of semiconductor material, and instead may include active regions of semiconductor material surrounded by field regions of isolation dielectric.

In some embodiments, the active devices within device layer 210 are field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, IC die device layer 210 may include active devices other than FETs. For example, IC die device layer 210 may include electronic memory structures, such as magnetic tunnel junctions (MTJs), capacitors, or the like. Accordingly, each IC die may be a fully functional ASIC, or may be a chiplet or tile that has more limited functionality supplementing the function of one or more other IC dies, chiplets, or tiles. A chiplet or tile may, for example, be any of a wireless radio circuit, microprocessor core, electronic memory circuit, floating point gate array (FPGA), power management and/or power supply circuit, or include a MEMS device. In some other examples, IC dies 204 include one or more banks of active repeater circuitry to improve multi-chip interconnects (e.g., network-on-chip architectures). A repeater bank may, for example, support 2000+ signals within an IC die area of no more than 0.4 mm². In other examples, IC dies 204 include clock generator circuitry or temperature sensing circuitry. In other examples, IC dies 204 include one or more ESD banks or include logic circuitry that, along with other IC die implements 3D logic circuitry (e.g., mesh network-on-chip architectures). In still other examples, IC dies 204 include microprocessor core circuitry, for example comprising one or more shift registers.

Wafer 201 has a front side 221 that comprises one or more IC die metallization levels 215. In exemplary embodiments, metallization levels 215 include metallization features 220 embedded within an insulator 218. While metallization features 220 may have any composition(s) of sufficient electrical conductivity, in exemplary embodiments, metallization features 220 are predominantly copper (Cu). In other examples, metallization features 220 are predominantly other than Cu, such as, but not limited to predominantly Ru, or predominantly W. An uppermost one of metallization layers 215 includes “bondable” metallization features 220 that have an associated feature pitch suitable for directly bonding to complementary conductive features of an IC die. This feature pitch may range from 100 nm to several microns, for example. Although not illustrated, wafer 201 may further include TSVs extending into substrate material 211. If so, IC die 204 may be subsequently thinned (e.g., after bonding) by removing at least some of substrate material 211 to expose the IC die TSVs.

Insulator 218 may have any composition(s) suitable as an electrical insulator. In exemplary embodiments, insulator 218 is an inorganic interlayer dielectric (ILD) material having any material composition known to be suitable as an insulator of monolithic integrated circuitry, such as, but not limited to, silicon dioxide, silicon nitride, silicon oxynitride, or a low-k material having a relative permittivity below 3.5. In some embodiments, ILD materials vary in composition with a lower ILD material layer 218 comprising a low-k dielectric material and an uppermost ILD material layer 218 comprising a conventional dielectric material (e.g., having a dielectric constant of approximately 3.5, or more). Confining low-k dielectric materials distal from a bond interface in this manner may advantageously improve bond strength and/or quality. In other embodiments where low-k dielectric material can form a strong bond interface, all ILD material layers 218 may all be a low-k material (e.g., having a relative permittivity of 1.5-3.0).

As further illustrated in FIG. 2, a kerf 207 between two adjacent IC dies 204 is removed during singulation, exposing two IC die edge sidewalls 225. In some embodiments, as further shown in FIG. 3A, the die singulation process generates die edge sidewalls 225 that are substantially normal to an x-y plane of front side 221. Although edge sidewall 225 is illustrated to be precisely at 90° of front side 221, edge sidewall 225 may vary by approximately +/−5° from normal (e.g., 85-95°) as a function of the singulation technique. For example, laser ablation may result in an edge sidewall 225 that deviates from normal by a larger amount than if singulation is by mechanical sawing.

Returning to FIG. 1, in accordance with some embodiments methods 100 continue at block 120 where the die edge sidewall is shaped after singulation. For alternative embodiments where singulated IC die are received as an input to methods 100, shaping performed at block 120 is distinct from the singulation process. However, for embodiments where die singulation is performed as part of methods 100, shaping at block 120 may be integrated with a singulation process performed at block 115. Regardless, shaping at block 120 advantageously comprises chamfering or radiusing IC die backside edges or corners. Chamfering or radiusing the backside corners may smoothen transitions between an edge sidewall of the IC die and a backside surface of the IC die. Chamfering or radiusing the backside corners may also advantageously smoothen out peaks and valleys of the IC die edges that may otherwise induce high stress centers when subsequently covered with a fill material.

Backside IC die edges or corners may be shaped with any process suitable for the die substrate composition. In some examples, one or more of a plasma etch process, a wet etch process, or an ultra-short pulse (e.g., femto- or pico-second) laser ablation process is employed to shape the backside IC die corners. In some exemplary embodiments where the backside of an IC die is substantially pure silicon, the IC die edge is shaped with anisotropic plasma silicon etch process (e.g., Bosch-type). Such an etch can be tuned from a moderately sloped etch profile typical of through vias to a highly sloped etch profile more suitable for chamfering the die edge sidewall. During a plasma etch, the IC die backside may be protected with a mask material. Controlled erosion of the mask material during an anisotropic etch of substrate material may be leveraged to define a substantially constant sidewall slope angle or a sidewall slope angle that varies over a corner radius. In other embodiments, at block 120 an angle of incidence of laser energy is controlled to a desired sidewall slope angle and substrate material is ablated along a path coincident with a perimeter edge of IC die to chamfer the IC die edge. In still other embodiments, at block 120 the backside of an IC die is polished with a pad of suitable hardness to erode edges of the backside at a rate significantly greater than at a center of the IC die and thereby shaping the backside edge for example to have a controlled radius.

Depending on the shaping technique employed at block 120, the edge of the IC die backside may be chamfered or radiused. FIG. 3B illustrates exemplary IC die 304, which are substantially identical to IC die 204 (FIG. 3A) except for the larger slope of a chamfered length L1 of edge sidewall 225. The chamfer reduces a thickness of an edge portion of IC die 304 over a distance D so that IC die 204 have a trapezoidal cross-sectional profile. Depending on the amount of chamfer, the edge portion of IC die 304 may have a thickness T2 that ranges from a minimal thickness T3 associated with device layer 210 and metallization levels 215 up to about 75% of IC die thickness T1. Although thickness T1 may vary within implementation, in some examples thickness T1 is in the range of 20-200 μm.

Sidewall chamfer length L1 may have a sidewall slope associated with angle α1 that is at least 10° from perpendicular of an xy plane of front die side 221. In some advantageous embodiments, at least some portion of edge sidewall 225 has a sidewall slope of at least 20° from normal to the xy plane of front die side 221. Although control over the slope may become more challenging as slope increases, some portions of edge sidewall 225 may have a sidewall slope of as much as 30-45°.

As denoted with a dashed line in FIG. 3B, the chamfer length L1 may vary. In some embodiments, where the chamfer nearly intersects device layer 210, the sidewall chamfer length L1 may be approximately equal to, or greater than, the thickness of substrate material 211. In other embodiments where the chamfer is limited to no more than 50% of the IC die thickness T1, chamfer length L1 may be at least 40% of the thickness of substrate material 211.

FIG. 3C illustrates an example of a corner radiused IC die 305, which is substantially identical to IC die 204 (FIG. 3A) except for sidewall 225 having an edge or corner radius R. Whereas a chamfered sidewall may have a substantially constant sidewall slope over a chamfer length, slope may vary nearly continuously over corner radius R. In exemplary embodiments, corner radius R is at least 50 μm. Advantageously, corner radius R is at least equal to 30% of IC die thickness T1 and may be as much as 100-150 μm.

Returning to FIG. 1, methods 100 continue with the receipt of a host substrate at input 118. The host substrate may have been fabricated upstream of methods 100 according to any suitable technique. In some embodiments, host substrate received at input 118 is a fully functional IC die or a chiplet or tile of more limited functionality, for example. The host substrate may also be a passive die lacking any transistors and/or device layer. The host substrate may also be any other structure known to be suitable as a package substrate or interposer.

At block 125, IC die(s) are bonded to the host substrate in a vertical stack-up to form a composite device structure comprising one or more IC dies on the host substrate. Notably, block 125 may also be performed prior to bock 120 (i.e., with die shaping occurring after die bonding). Die bonding may be according to any alignment and bonding process suitable for the IC die and host substrate. For example, an IC die of a relatively large edge length may be handled and aligned to a target location on the host substrate according to pick-and-place die assembly methods and systems. Many such methods and systems can handle an object as thin as 50-100 μm and with sidewall edge length ranging from tens of millimeters down to ˜200 μm. Die attachment may also comprise one or more micro device assembly techniques including so-called transfer printing methods, which can accommodate an object as thin as 1 μm and having lateral dimensions in the tens of micrometers. Such micro device assembly techniques may rely on a MEMS microtool that includes hundreds or even thousands of die attachment points. Micro device assembly methods and systems suitable for inorganic LED (iLED) technology, for example, may be employed to transfer a plurality of IC chiplets concurrently from a source IC die substrate to multiple host substrates arrayed within a wafer or panel.

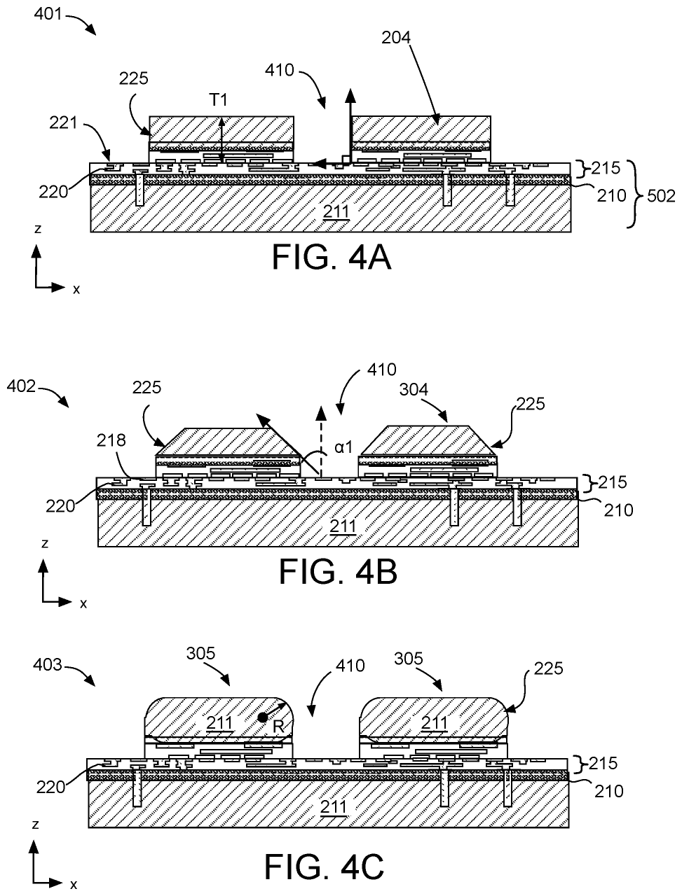

In the example further illustrated in FIG. 4A, a plurality of IC die, including at least one IC die 204, is aligned and bonded to a host substrate 502. Host substrate 502 includes substrate material 211, and metallization levels 215 which may have any of the properties described above for IC die 204, for example. As shown, metallization features 220 on IC die 204 are directly bonded to metallization features 220 on host substrate front side 221. Hence, IC dies may be “face-to-face” bonded where features on a front-side of IC dies are bonded to features on a front-side of host substrate 502. In alternative embodiments, IC dies may be “face-to-back” bonded to host substrate 502. If IC dies are instead to be “back-to-back” bonded to host substrate 502, the shaping described herein may instead be performed on the frontside of an IC die.

In the cross-sectional view of a composite IC die structure 401, IC die 204 is adjacent to another IC die with a space 410 between their nearest edge sidewalls 225. Hybrid bonding surfaces of the IC dies are substantially co-planar. The IC dies may be aligned to a target location on host substrate 502 with any high-resolution alignment tool, for example of the type found on a wafer-level or chip-level bonding tool commercially available through several industry suppliers. Alignment capability continues to advance, having improved from +/−5 μm to +/−0.2 μm over recent years. Direct bonding of the host substrate to the dies may be metal-to-metal, for example, during which metallization features sinter. In some embodiments, a hybrid bond is formed both between metallization features (e.g., via metal interdiffusion) and between dielectric materials (e.g., via Si—O—Si condensation bonds). Thermo-compression bonding may be at low temperature (e.g., below melting temperature of the interconnects, and more specifically below 100° C.). Direct bonding at room temperature (i.e., compression only) is also possible. Prior to bonding, host substrate and/or IC dies may be pre-processed, for example with a plasma clean, to activate their surfaces for the bonding. Post bonding, selective heating may be performed to make permanent the bond (e.g., by converting a Van Der Waals bond into a sintered Cu—Cu bond through interdiffusion). For selective heating, a laser may be employed to successively heat individual IC die.

In some embodiments, lateral (e.g., x-axis) misalignment or misregistration between conductive features of host substrate 502 and IC die 204 is less than 0.2 μm. For example, lateral misalignment between one conductive feature (e.g., a line or trace) and another conductive feature (e.g., a via) within a monolithic IC die may be at least an order of magnitude smaller than the lateral misalignment between bonded conductive features. The lateral dimensions of metallization features at the bond interface are sufficiently large to accommodate such lateral offset. Where multiple IC die are bonded individually to host substrate 502, the magnitude of the lateral offset may vary between the IC dies.

As shown in FIG. 4A, the nearly orthogonal IC die edge sidewall 225 has similar orthogonality to host substrate front side 221 as a bond plane between IC die 204 and host substrate 502 is substantially planar with host substrate front side 221. Accordingly, die gap 410 between two adjacent IC dies has a first aspect ratio dependent upon IC die thickness T1 and the width (e.g., x-dimension) of die gap 410. The lateral width between nearest IC die edge sidewalls 225 may vary, for example from 5-100 μm, depending on clearance needed for IC die alignment during a bonding process. In some examples, the aspect ratio of die gap 410 is greater than 1:1. In contrast, for composite IC die structure 402 illustrated in FIG. 4B, the plurality of IC dies include IC die 304, which has chamfered sidewall 225 with slope angle α1 relative to host substrate frontside 221. As noted above, sidewall slope angle α1 may be at least 10° from perpendicular to host substrate front surface 221. Accordingly, die gap 510 has a more relaxed aspect ratio (e.g., less than 1:1).

Similarly, composite IC die structure 403 illustrated in FIG. 4C comprises a plurality of IC dies that includes IC die 305, which has radiused sidewall 225. Relative to composite IC die structure 401, die gap 410 again has a more relaxed aspect ratio (e.g., less than 1.0). Also, the transition between a nearly vertical (e.g., z-axis) edge sidewall to a substantially horizontal (e.g., x-y axes) die backside is more gradual for IC die 305 than for the geometry of IC die 204 (FIG. 4A).

Returning to FIG. 1, methods 100 continue at block 130 where a crack barrier is deposited over the IC die. Block 130 may be practiced in embodiments of methods 100 where IC die are not shaped at block 120 (i.e., where block 120 is skipped). Block 130 may also be practiced in combination with IC die shaping at block 120 (i.e., both blocks 120 and 130 are performed) because the practice of block 130 may reduce the demands on shaping at block 120. However, in some embodiments where IC die are shaped at block 120, no crack barrier is deposited (i.e., block 130 is skipped).

At block 130, an inorganic an organic material is deposited over the IC die bonded to the host substrate. Inorganic barrier layer materials may be deposited at block 130 by chemical vapor deposition (CVD) or plasma enhanced (PE) CVD, for example. Organic barrier layer materials may be deposited at block 130 either by plasma deposition, or spin-on coating, for example. The barrier layer may provide a mechanical buffer to accommodate local roughness on the IC die or chiplet surfaces and smoothen the geometry or topography along an IC die edge, reducing a likelihood of developing stress cracks during subsequent processing. The barrier material deposited at block 130 may also have a greater modulus of toughness than an inorganic material subsequently deposited to backfill gaps between the IC dies. The greater modulus of toughness may prevent cracks initiated within an overlying inorganic fill material from propagating into the underly IC dies.

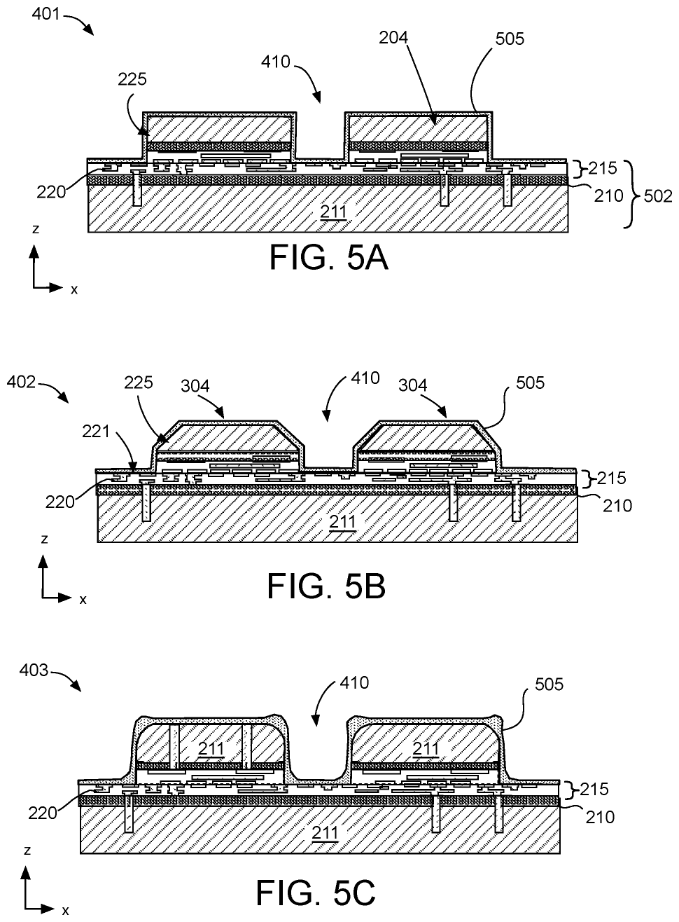

In some embodiments, the barrier layer deposited at block 130 has a thickness less than 5 μm. Where a conformal deposition is practiced at block 130, the barrier layer may have a substantially conformal thickness of 1 μm, or less. In the example illustrated in FIG. 5A, a crack barrier material 505 has been conformally deposited over IC die 204. Barrier material 505 is therefor in direct contact with both die edge sidewall 225 and a top surface of host substrate 502 between adjacent IC dies. In the absence of any die edge shaping, barrier material 505 is relied upon to protect IC die 204 from any cracks subsequently induced by the nearly vertical edge sidewalls 225.

In some embodiments, crack barrier material 505 is an inorganic material comprising at two or more of silicon, carbon or nitrogen. As one example, crack barrier material 505 may be Si₃N₄ (SiN). In another example, crack barrier material 505 is SiC. In another example, crack barrier material 505 is SiCN. In some alternative embodiments, crack barrier material 505 is a polymeric, or organic, material. As one example, crack barrier material 505 is polyimide.

FIG. 5B further illustrates an example where composite IC structure 402 includes both shaped IC die 304 and crack barrier material 505, which may have any of the properties described above. FIG. 5C further illustrates an example where composite IC structure 403 includes both shaped IC die 305 and crack barrier material 505, which may have any of the properties described above. In contrast to the substantially conformal barrier layers illustrated in FIG. 5A-5B, composite IC structure 403 includes a non-conformal barrier layer 505 more typical of an organic material that has been spin-coated and cured.

Returning to FIG. 1, methods 100 continue at block 135 where a barrier material (if present) may be optionally etched back either to reduce the barrier material thickness or to remove a portion of the barrier material from certain regions of a composite IC device structure. Any etch process suitable for the composition of the barrier material may be practiced at block 135. In some examples where the barrier material is an inorganic material, the etch process may be isotropic or anisotropic. The etch process may be masked to retain the barrier material at only predetermined locations. Alternatively, an anisotropic etch process may be unmasked (i.e., a blanket etch) to retain only a spacer of barrier material that is self-aligned to edge sidewalls of the IC dies. Similar etch process may be practiced for other examples where the barrier material is an organic material. For example, an oxygen-based plasma etch may be practiced at block 135 to remove some predetermined target thickness of barrier material.

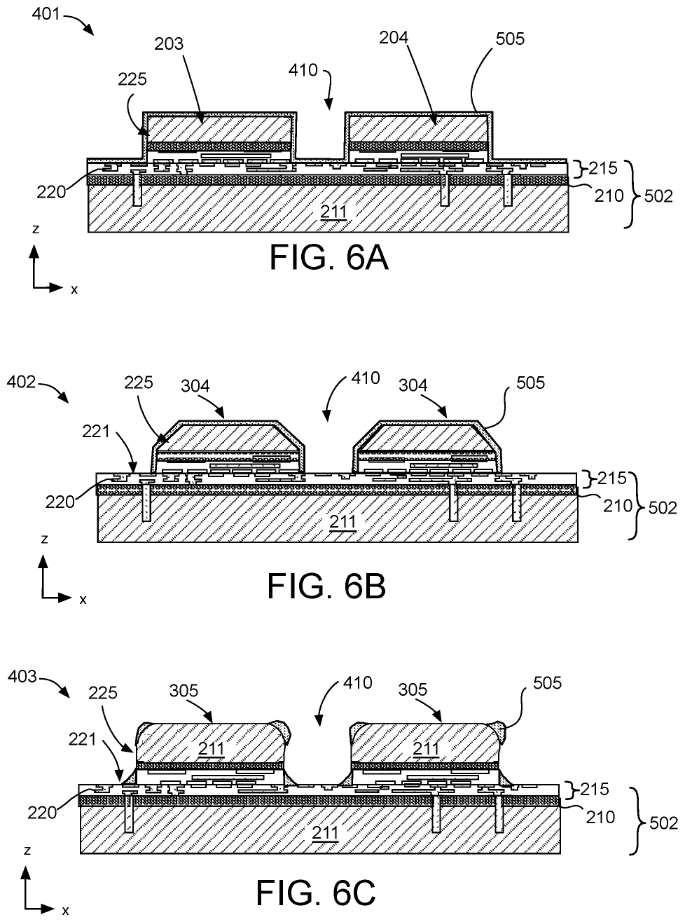

FIG. 6A illustrates one example where no barrier layer etchback is performed so that barrier layer 505 remains substantially as-deposited (i.e., identical to FIG. 5A). FIG. 6B illustrates an alternative embodiment where a masked etch process removed barrier material 505 from surfaces of host substrate 502 while retaining barrier material 505 over substantially all exposed surfaces of IC die 305. FIG. 6C illustrates another alternative embodiment where an unmasked etch has removed a thickness of barrier material 505 so that barrier material is removed both from a portion of host substrate surface 221 and from a portion of IC die edge sidewall 225. Barrier material 505 is retained only where the local thickness according to surface topography of composite IC die structure 403 exceeds the thickness removed by the etchback process.

Returning to FIG. 1, methods 100 continue with the formation of fill material over the IC die bonded to the host substrate. In exemplary embodiments, one or more layers of inorganic material is deposited at block 140. In some embodiments, an inorganic material is deposited by CVD or PECVD. The PECVD deposition may comprise a high-density plasma process (HDP-CVD), which offer good gap filling performance for aspect ratios exceeding 1:1.

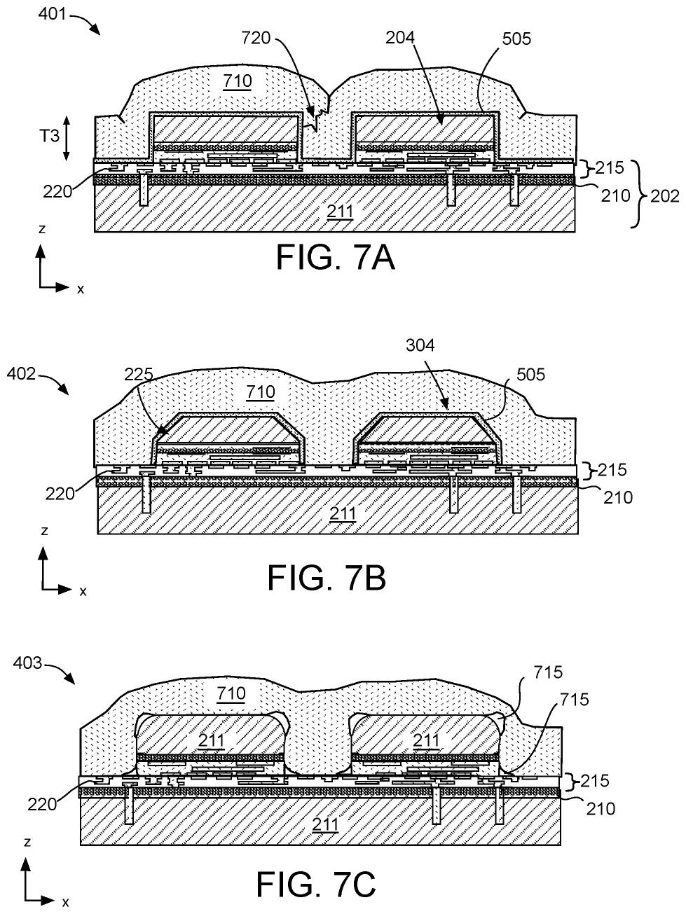

In the example illustrated in FIG. 7A, composite IC die structure 401 now includes an inorganic fill material 710, which has been deposited over IC die 204 and intervening regions of host substrate 502. Inorganic fill material 710 has an as-deposited thickness T3, which may vary with implementation. In the illustrated embodiment, as-deposited thickness T3 is greater than the IC die thickness. In some examples, as-deposited thickness T3 is in the range of 20-200 μm.

Inorganic fill material 710 may have any composition known to be suitable for gap fill in the context of monolithic IC fabrication. In exemplary embodiments, inorganic fill material 710 is a dielectric material. For some embodiments including barrier layer 505, inorganic fill material 710 has a lower modulus of toughness than that of barrier layer 505. Exemplary inorganic dielectric materials comprise predominantly silicon and oxygen. In some embodiments, inorganic fill material 710 is substantially SiO₂. In other embodiments, inorganic fill material 710 has significant nitrogen and/or carbon content (e.g., SiN, SiC, SiON, SiOC, SiONC, α-C, etc.). In embodiments where barrier layer 505 also comprises nitrogen and/or carbon, inorganic fill material 710 preferably has a lower content of nitrogen and/or carbon than barrier layer 505.

For higher deposition rates, conformality of inorganic fill material 710 may suffer and topographic shadowing effects may occur. Inorganic fill material 710 may therefore have some cusping and/or “bread loafing” because of underlying IC die topography and a steep sidewall slope that reduces the rate of material deposition upon IC die edges 225 relative to the top of the IC dies. Inorganic compositions are advantageous for their low stress and/or good CTE match with IC die, low dielectric constant, and/or high thermal conductivity. However, at greater thicknesses, film cracks 720 can form within fill material 710. Such film cracks may be prevalent in composite IC die structure 401 since IC die 204 was not shaped in accordance with other embodiments herein. Nevertheless, film cracks 720 terminate at the interface of barrier layer 505 so that IC die 204 is not negatively impacted by film cracks 720.

FIG. 7B further illustrates composite IC die structure 402 following deposition of inorganic fill material 710, which may have any of the compositions described above. With chamfered edge sidewalls 225, bread-loafing and/or other effects of deposition shadowing are relatively less and stress within inorganic fill material 710 may be sufficiently low to avoid any film cracks. However, if any cracks were to develop within fill material 710, the presence of barrier layer 505 may further act to prevent their propagation into IC die 304.

FIG. 7C further illustrates composite IC die structure 403 following deposition of inorganic fill material 710, which may have any of the compositions described above. FIG. 7C further illustrates an example where barrier layer material 505 (FIG. 6C) has been decomposed subsequent to the deposition of fill material 710. The barrier material decomposition generates voids 715 at the locations where barrier material was present. For embodiments where the barrier material is an organic composition, voids 715 may be formed through thermal decomposition. However, UV and/or laser irradiation techniques may also be enlisted to remove similarly sacrificial barrier material having an alternative chemical composition. Because stress may tend to concentrate at the die edge/corner area due to the interaction of inorganic fill material and the die, the pockets or voids 715 may minimize stress concentration to a point that no film cracks occur. Hence, in the example illustrated, composite IC die structure 403 is substantially crack free. However, if film cracks do occur, they should terminate at void(s) 715 without entering the IC die. Notably, voids 715 are limited in their area so that fill material 710 does not suffer poor adhesion. Hence, the location of the voids 715 is advantageously coincident with where stress centers arise within fill material 710.

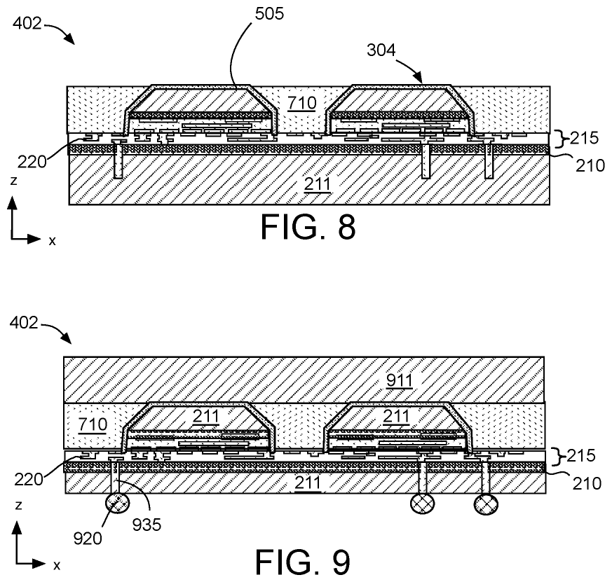

Returning to FIG. 1, methods 100 then continue at block 145 where the fill is globally planarized. The fill material may be planarized to a surface of one or more of the IC dies embedded within the fill material, for example. In the example further illustrated in FIG. 8, a grind, polish, or other planarization process has removed an overburden of the inorganic fill material 710 from composited IC die structure 402 to expose crack barrier layer 505 and/or surfaces of at least IC die 304. Planarizing of the fill material may remove some of the film cracks that may have developed during processing.

Returning to FIG. 1, methods 100 end at output 150 where the composite IC die structure is completed. In some examples, completion of the composite IC die structure comprises the fabrication of one or more metallization features, such as through vias, within the gap fill material (not depicted). The fabrication of through vias may, for example, comprise a patterned etch process that forms via openings and a metal deposition process that fills the via openings with a metal. Such processing is optional, however, and may be excluded from the practice of methods 100.

In some embodiments, completion of the multi-die composite IC structure entails stacking another level of IC die upon one or more of the IC dies already in the composite structure. In other embodiments, completion of the composite IC die structure comprises stacking a structural member upon one or more IC dies and/or the surrounding die gap fill. In the example further illustrated in FIG. 9, a preform 911 has been bonded to fill material 710. Preform 911 may also be directly bonded to IC dies embedded within fill material 170. Preform 911 may be another active IC die, a passive interconnect die, or a purely structural member, for example. Unlike another functional IC die, a structural member may be exclusively for mechanical support and completely passive with no active devices (e.g., transistors) or interconnect metallization routes. Although the composition of preform 911 may therefore vary, in some embodiments preform 911 comprises monocrystalline silicon. In other embodiments, preform 911 is predominantly a glass (e.g., silica). In still other embodiments, preform 911 comprises an electrically conductive material (e.g., in the form of a metal foil, or including patterned traces, etc.).

Following the completion of a composite IC die structure in accordance with embodiments herein, first level interconnects (FLI) may be formed on exposed surfaces of conductive features of the composite structure in preparation for packaging or assembly. In exemplary embodiments, solder features are formed as the FLI. The composite IC die structure may then be singulated according to any techniques known to be suitable for monolithic IC die. FIG. 9 further illustrates one example where host substrate material 211 is thinned to expose through vias 935. FLI interconnects 920 are then coupled to through vias 935 according to any suitable technique.

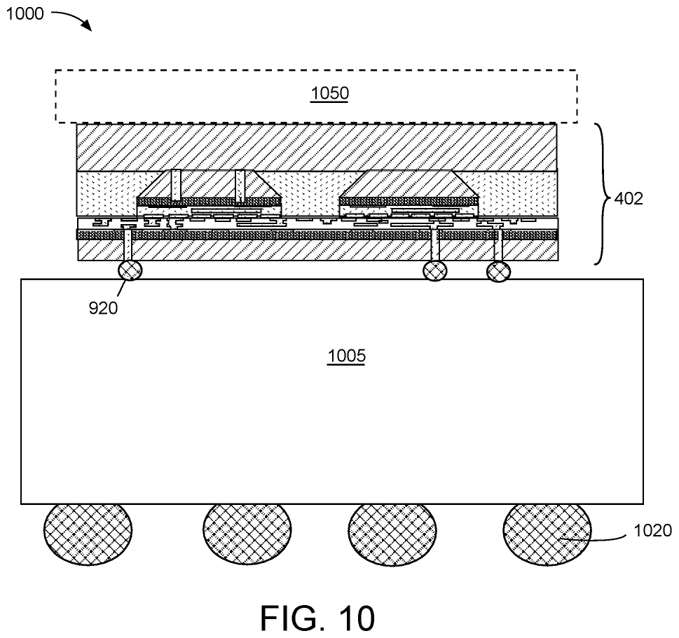

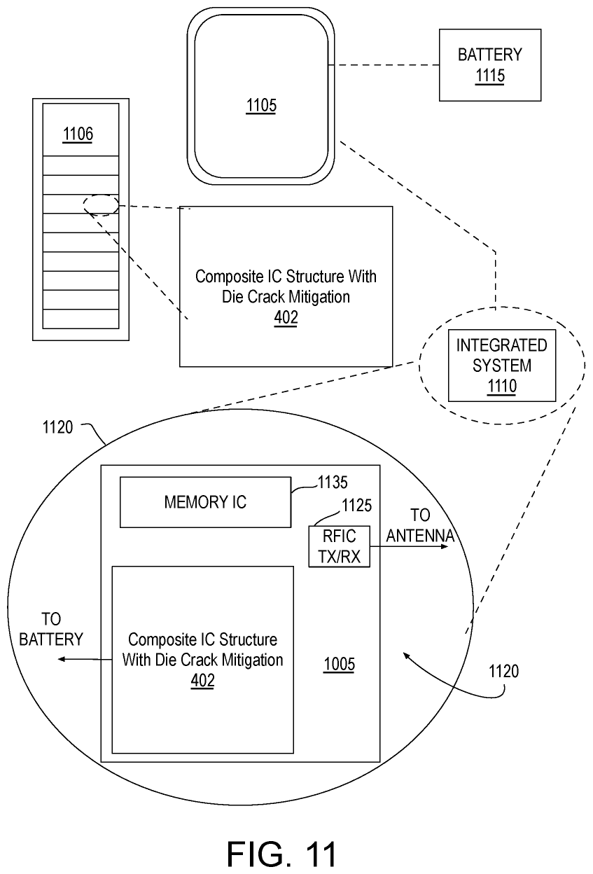

FIG. 10 illustrates a system including IC die composite structure 402 attached to a host component 1005 by reflowing FLI interconnects 920. In exemplary embodiments, FLI interconnects 920 are solder (e.g., SAC) microbumps although other interconnect features are also possible. In some embodiments, host component 1005 is predominantly silicon. Host component 1005 may also comprise one or more alternative materials known to be suitable as interposers or package substrates (e.g., an epoxy preform, cored or coreless laminate board, etc.). Host component 1005 may include one or more metallized redistribution levels (not depicted) embedded within a dielectric material. Host component 1005 may also include one or more IC die embedded therein. For example, an IC interconnect bridge (not depicted) may be embedded within metallized redistribution levels of host component 1005, for example to electrically couple composite IC die structure 402 to another IC die or composite IC die structure.

Host component 1005 (e.g., a package substrate) may be further coupled to a system-level host, such as a mother board or other PCB, by second level interconnects (SLI) 1020. SLI 1020 may comprise any solder (ball, bump, etc.) suitable for a given host board architecture (e.g., surface mount FR4, etc.). As illustrated in dashed line, one or more heat spreaders and/or heat sinks 1050 may be further coupled to composite IC die structure 402, which may be advantageous, for example, where composite IC die structure 402 comprises one or more CPU cores or other IC die of similar power density.

FIG. 11 illustrates a mobile computing platform 1105 and a data server machine 1106 employing a composite IC die structure comprising a crack mitigation structure, for example as described elsewhere herein. Server machine 1106 may be any commercial server, for example including any number of high-performance computing platforms disposed within a rack and networked together for electronic data processing, which in the exemplary embodiment includes composite IC die structure 402, for example as described elsewhere herein. The mobile computing platform 1105 may be any portable device configured for each of electronic data display, electronic data processing, wireless electronic data transmission, or the like. For example, the mobile computing platform 1105 may be any of a tablet, a smart phone, laptop computer, etc., and may include a display screen (e.g., a capacitive, inductive, resistive, or optical touchscreen), an integrated system 1110, and a battery 1115.

As illustrated in the expanded view 1120, composite IC die structure 402 is further coupled to host component 1005, along with one or more memory IC 1135. One or more of a power management integrated circuit (PMIC) 1130 or RF (wireless) integrated circuit (RFIC) 1125 including a wideband RF (wireless) transmitter and/or receiver may be further coupled to host component 1005. PMIC 1130 may perform battery power regulation, DC-to-DC conversion, etc., and so has an input coupled to battery 1115 and with an output providing a current supply to other functional modules. As further illustrated, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

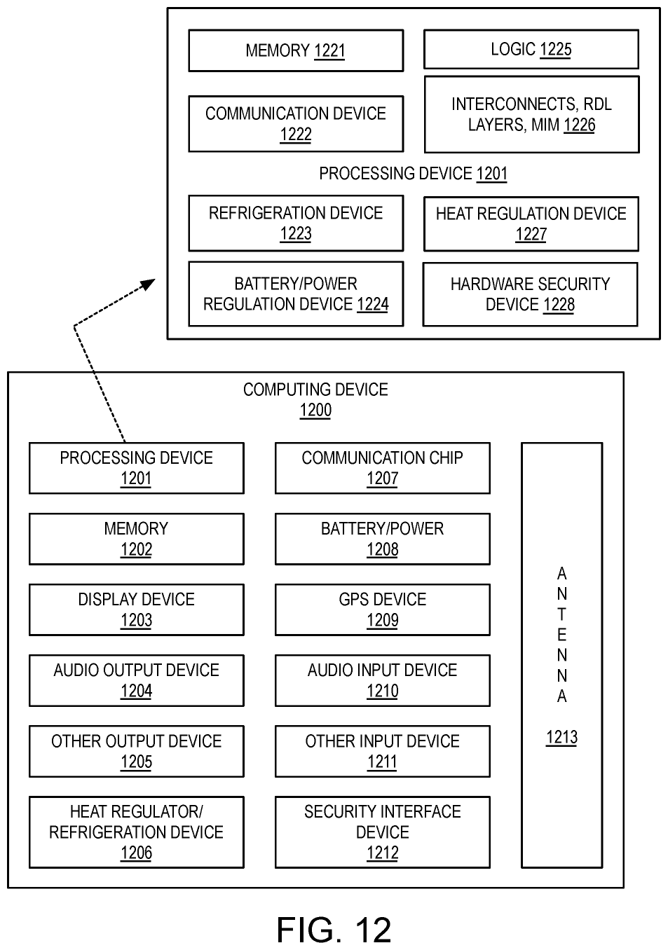

FIG. 12 is a block diagram of a cryogenically cooled computing device 1200 in accordance with some embodiments. For example, one or more components of computing device 1200 may include any of the devices or structures discussed elsewhere herein. A number of components are illustrated in FIG. 12 as included in computing device 1200, but any one or more of these components may be omitted or duplicated, as suitable for the application. In some embodiments, some or all of the components included in computing device 1200 may be attached to one or more printed circuit boards (e.g., a motherboard). In some embodiments, various ones of these components may be fabricated onto a single system-on-a-chip (SoC) die. Additionally, in various embodiments, computing device 1200 may not include one or more of the components illustrated in FIG. 12, but computing device 1200 may include interface circuitry for coupling to the one or more components. For example, computing device 1200 may not include a display device 1203, but may include display device interface circuitry (e.g., a connector and driver circuitry) to which display device 1203 may be coupled.

Computing device 1200 may include a processing device 901 (e.g., one or more processing devices). As used herein, the term processing device or processor indicates a device that processes electronic data from registers and/or memory to transform that electronic data into other electronic data that may be stored in registers and/or memory. Processing device 801 may include a memory 1221, a communication device 1222, a refrigeration/active cooling device 1223, a battery/power regulation device 1224, logic 1225, interconnects 1226 (i.e., optionally including redistribution layers (RDL) or metal-insulator-metal (MIM) devices), a heat regulation device 1227, and a hardware security device 1228.

Processing device 1201 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1201 may include a memory 1202, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1221 includes memory that shares a die with processing device 1202. This memory may be used as cache memory and may include embedded dynamic random-access memory (eDRAM) or spin transfer torque magnetic random-access memory (STT-M RAM).

Computing device 1200 may include a heat regulation/refrigeration device 1206. Heat regulation/refrigeration device 1206 may maintain processing device 1202 (and/or other components of computing device 1200) at a predetermined low temperature during operation. This predetermined low temperature may be any temperature discussed elsewhere herein.

In some embodiments, computing device 1200 may include a communication chip 1207 (e.g., one or more communication chips). For example, the communication chip 1207 may be configured for managing wireless communications for the transfer of data to and from computing device 1200. The term “wireless” and its derivatives may be used to describe circuits, devices, systems, methods, techniques, communications channels, etc., that may communicate data through the use of modulated electromagnetic radiation through a nonsolid medium.

Communication chip 1207 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1207 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1207 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1207 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1207 may operate in accordance with other wireless protocols in other embodiments. Computing device 1200 may include an antenna 1213 to facilitate wireless communications and/or to receive other wireless communications (such as AM or FM radio transmissions).

In some embodiments, communication chip 1207 may manage wired communications, such as electrical, optical, or any other suitable communication protocols (e.g., the Ethernet). As noted above, communication chip 1207 may include multiple communication chips. For instance, a first communication chip 1207 may be dedicated to shorter-range wireless communications such as Wi-Fi or Bluetooth, and a second communication chip 1207 may be dedicated to longer-range wireless communications such as GPS, EDGE, GPRS, CDMA, WiMAX, LTE, EV-DO, or others. In some embodiments, a first communication chip 1207 may be dedicated to wireless communications, and a second communication chip 1207 may be dedicated to wired communications.

Computing device 1200 may include battery/power circuitry 1208. Battery/power circuitry 1208 may include one or more energy storage devices (e.g., batteries or capacitors) and/or circuitry for coupling components of computing device 1200 to an energy source separate from computing device 1200 (e.g., AC line power).

Computing device 1200 may include a display device 1203 (or corresponding interface circuitry, as discussed above). Display device 1203 may include any visual indicators, such as a heads-up display, a computer monitor, a projector, a touchscreen display, a liquid crystal display (LCD), a light-emitting diode display, or a flat panel display, for example.

Computing device 1200 may include an audio output device 1204 (or corresponding interface circuitry, as discussed above). Audio output device 1204 may include any device that generates an audible indicator, such as speakers, headsets, or earbuds, for example.

Computing device 1200 may include an audio input device 1210 (or corresponding interface circuitry, as discussed above). Audio input device 1210 may include any device that generates a signal representative of a sound, such as microphones, microphone arrays, or digital instruments (e.g., instruments having a musical instrument digital interface (MIDI) output).

Computing device 1200 may include a global positioning system (GPS) device 1209 (or corresponding interface circuitry, as discussed above). GPS device 1209 may be in communication with a satellite-based system and may receive a location of computing device 1200, as known in the art.

Computing device 1200 may include another output device 1205 (or corresponding interface circuitry, as discussed above). Examples include an audio codec, a video codec, a printer, a wired or wireless transmitter for providing information to other devices, or an additional storage device.

Computing device 1200 may include another input device 1211 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1200 may include a security interface device 1212. Security interface device 1212 may include any device that provides security measures for computing device 1200 such as intrusion detection, biometric validation, security encode or decode, managing access lists, malware detection, or spyware detection.

Computing device 1200, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described but can be practiced with modification and alteration without departing from the scope of the appended claims. For example, the above embodiments may include specific combinations of features as further provided below.

In first examples, an integrated circuit (IC) device comprises a first IC die directly bonded to a first region of a host substrate and a second IC die directly bonded to a second region of the host substrate. Each of the first IC die and second IC die comprises at least one of a corner, distal from the host substrate, having a radius of curvature exceeding 50 μm or an edge sidewall with a slope that is at least 10° from normal to a plane of the host substrate. The IC device comprises a fill comprising at least a first inorganic material within a space between the first and second IC dies.

In second examples, for any of the first examples the corner has a radius of curvature exceeding 100 μm or the edge sidewall has a slope that is at least 20° from normal to the plane of the host substrate.

In third examples, for any of the first through second examples each of the first IC die and second IC die has a trapezoidal cross-section.

In fourth examples, for any of the first through second examples each of the first IC die and second IC die comprises a sidewall with a slope at least 30° from normal to the plane of the host substrate.

In fifth examples, for any of the first through fifth examples, the IC device further comprises a barrier layer between the fill and each of the first IC die and second IC die, wherein the barrier layer has a thickness less than 5 μm

In sixth examples, for any of the fifth examples the barrier layer has a thickness less than 1 μm.

In seventh examples for any of the fifth through sixth examples the barrier layer comprises a material that has modulus of toughness exceeding that of the first inorganic material.

In eighth examples, for any of the fifth examples the barrier layer comprises a material with an organic composition.

In ninth examples, for any of the eighth examples the barrier layer comprises polyimide.

In tenth examples, for any of the fifth examples the barrier layer comprises a material with an inorganic composition.

In eleventh examples, for any of the tenth examples the barrier layer comprises two or more of silicon, carbon, or nitrogen.

In twelfth examples, for any of the first through eleventh examples the first inorganic material comprises predominantly silicon and oxygen.

In thirteenth examples, for any of the first through twelfth examples the first inorganic material is spaced apart from at least the corner of each of the first IC die and the second IC die by a void.

In fourteenth examples, for any of the first through thirteenth examples a surface of the fill is substantially co-planar with a surface of at least one of the first or second IC dies and a third IC die, a passive interconnect structure, or a purely structural member bonded to a top surface of the fill.

In fifteenth examples, a system comprises a host component and a composite integrated circuit (IC) device attached to the host component. The composite IC device comprises a host substrate, a first IC bonded to a first region of a host substrate, and a second IC die bonded to a second region of the host substrate. Each of the first IC die and second IC die comprises at least one of a corner, distal from the host substrate, having a radius of curvature exceeding 50 μm, or an edge sidewall with a slope that is at least 10° from normal to a plane of the host substrate. The composite IC device comprises a fill comprising at least a first inorganic material within a space between the first and second IC dies. The composite IC device further comprises a third IC die, a passive interconnect structure, or a purely structural member bonded to a top surface of the fill.

In sixteenth examples, for any of the fifteenth examples the system comprises a power supply coupled to provide power to the composite IC device through the host component.

In seventeenth examples, for any of the fifteenth through sixteenth examples the host substrate is coupled to the host component through a plurality of first solder interconnects.

In eighteenth examples, for any of the fifteenth through seventeenth examples the first IC die is a first of a microprocessor core circuitry, wireless radio circuitry, floating point gate array (FPGA) circuitry, power management circuitry, active repeater circuitry, clock generator circuitry, memory circuitry, or input/output buffer circuitry. The second IC die is a second of a microprocessor core circuitry, wireless radio circuitry, floating point gate array (FPGA) circuitry, power management circuitry, active repeater circuitry, clock generator circuitry, memory circuitry, or input/output buffer circuitry.

In nineteenth examples, a method of assembling an integrated circuit (IC) device comprises bonding a first IC die to a first region of the host substrate. The first IC die has at least one of a corner, distal from the host substrate, with a radius of curvature exceeding 50 μm, or an edge sidewall with a slope that is at least 10° from normal to a plane of the host substrate. The method comprises bonding a second IC die to a second region of the host substrate. The second IC die has at least one of a corner, distal from the host substrate, with a radius of curvature exceeding 50 μm, or an edge sidewall with a slope that is at least 10° from normal to a plane of the host substrate. The method comprises depositing an inorganic fill material within a space between the first and second IC dies.

In twentieth examples, for any of the nineteenth examples the method comprises chamfering or radiusing the first and second IC dies by removing material from a perimeter edge of the first IC die and the second IC die.

In twenty-first examples, for any of the twentieth examples removing material from the perimeter edge comprises at least one of plasma etching, wet etching, or laser ablating, a substrate portion of the first IC die or the second IC die.

In twenty-second for any of the nineteenth through twenty-first examples the method further comprises depositing a barrier layer over the first IC die and the second IC die after bonding and prior to depositing the inorganic fill material.

In twenty-third examples, for any of the twenty-second examples depositing the barrier layer comprises conformally depositing, with a chemical vapor deposition process, an inorganic material layer comprising two or more of silicon, carbon, or nitrogen to a thickness less 5 μm.

In twenty-fourth examples, for any of the twenty-third examples depositing the barrier layer comprises coating first and second IC die with an organic material.

In twenty-fifth examples, for any of the nineteenth through twenty-fourth examples the method further comprises forming a void between the fill material and the IC die by decomposing at least a portion of the barrier layer after depositing the fill material.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. An integrated circuit (IC) device, comprising:
a first IC die directly bonded to a first region of a host substrate;
a second IC die directly bonded to a second region of the host substrate, wherein each of the first IC die and second IC die comprises at least one of:
a corner, distal from the host substrate, having a radius of curvature exceeding 50 μm; or
an edge sidewall with a slope that is at least 10° from normal to a plane of the host substrate; and
a fill comprising at least a first inorganic material within a space between the first and second IC dies.

2. The IC device of claim 1, wherein the corner has a radius of curvature exceeding 100 μm or the edge sidewall has a slope that is at least 20° from normal to the plane of the host substrate.

3. The IC device of claim 1, wherein each of the first IC die and second IC die has a trapezoidal cross-section.

4. The IC device of claim 1, wherein each of the first IC die and second IC die comprises a sidewall with a slope at least 30° from normal to the plane of the host substrate.

5. The IC device of claim 1, further comprising a barrier layer between the fill and each of the first IC die and second IC die, wherein the barrier layer has a thickness less than 5 μm.

6. The IC device of claim 5, wherein the barrier layer has a thickness less than 1 μm.

7. The IC device of claim 5, wherein the barrier layer comprises a material that has modulus of toughness exceeding that of the first inorganic material.

8. The IC device of claim 5, wherein the barrier layer comprises a material with an organic composition.

9. The IC device of claim 8, wherein the barrier layer comprises polyimide.

10. The IC device of claim 5, wherein the barrier layer comprises a material with an inorganic composition.

11. The IC device of claim 10, wherein the barrier layer comprises two or more of silicon, carbon, or nitrogen.

12. The IC device of claim 1, wherein the first inorganic material comprises predominantly silicon and oxygen.

13. The IC device of claim 1, wherein the first inorganic material is spaced apart from at least the corner of each of the first IC die and the second IC die by a void.

14. The IC device of claim 1, wherein:
a surface of the fill is substantially co-planar with a surface of at least one of the first or second IC dies; and
a third IC die, a passive interconnect structure, or a purely structural member is bonded to a top surface of the fill.

15. A system comprising:
a host component; and
a composite integrated circuit (IC) device attached to the host component, the composite IC device comprising:
a host substrate;
a first IC bonded to a first region of a host substrate;
a second IC die bonded to a second region of the host substrate, wherein each of the first IC die and second IC die comprises at least one of:
a corner, distal from the host substrate, having a radius of curvature exceeding 50 μm; or
an edge sidewall with a slope that is at least 10° from normal to a plane of the host substrate;
a fill comprising at least a first inorganic material within a space between the first and second IC dies; and
a third IC die, a passive interconnect structure, or a purely structural member bonded to a top surface of the fill.

16. The system of claim 15, further comprising:
a power supply coupled to provide power to the composite IC device through the host component.

17. The system of claim 15, wherein the host substrate is coupled to the host component through a plurality of first solder interconnects.

18. The system of claim 15, wherein:
the first IC die is a first of a microprocessor core circuitry, wireless radio circuitry, floating point gate array (FPGA) circuitry, power management circuitry, active repeater circuitry, clock generator circuitry, memory circuitry, or input/output buffer circuitry; and
the second IC die is a second of a microprocessor core circuitry, wireless radio circuitry, floating point gate array (FPGA) circuitry, power management circuitry, active repeater circuitry, clock generator circuitry, memory circuitry, or input/output buffer circuitry.

19. A method of assembling an integrated circuit (IC) device, the method comprising:
bonding a first IC die to a first region of the host substrate, wherein the first IC die has at least one of a corner, distal from the host substrate, with a radius of curvature exceeding 50 μm, or an edge sidewall with a slope that is at least 10° from normal to a plane of the host substrate;
bonding a second IC die to a second region of the host substrate, wherein the second IC die has at least one of a corner, distal from the host substrate, with a radius of curvature exceeding 50 μm, or an edge sidewall with a slope that is at least 10° from normal to a plane of the host substrate; and
depositing an inorganic fill material within a space between the first and second IC dies.

20. The method of claim 19, further comprising chamfering or radiusing the first and second IC dies by removing material from a perimeter edge of the first IC die and the second IC die.

21. The method of claim 20, wherein removing material from the perimeter edge comprises at least one of plasma etching, wet etching, or laser ablating, a substrate portion of the first IC die or the second IC die.

22. The method of claim 20, further comprising depositing a barrier layer over the first IC die and the second IC die after bonding and prior to depositing the inorganic fill material.

23. The method of claim 22, wherein depositing the barrier layer comprises conformally depositing, with a chemical vapor deposition process, an inorganic material layer comprising two or more of silicon, carbon, or nitrogen to a thickness less 5 μm.

24. The method of claim 22, wherein depositing the barrier layer comprises coating first and second IC die with an organic material.

25. The method of claim 22, further comprising forming a void between the fill material and the IC die by decomposing at least a portion of the barrier layer after depositing the fill material.
